(19) United States
(12) Patent Application Publication
(10) Pub. No.: US 2016/0037631 A1
(43) Pub. Date: Feb. 4, 2016

(54) DISPLAY APPARATUS WITH NARROW BEZEL

(71) Applicant: PIXTRONIX, INC., San Diego, CA (US)

(72) Inventor: Richard Steven Payne, Estero, FL (US)

(21) Appl. No.: 14/445,438

(22) Filed: Jul. 29, 2014

(51) Int. Cl. H05K 1/03; H05K 3/32; H05K 1/14; H05K 3/30; H05K 1/02; H05K 1/11

(52) U.S. Cl. CPC H05K 1/0306; H05K 1/0298; H05K 1/111; H05K 1/144; H05K 3/305; H05K 3/32; H05K 2201/09009; H05K 2203/173

(57) ABSTRACT

This disclosure describes a display having a substrate including a surface and a first plurality of routing lines on the surface. Each of the first plurality of routing lines is separated from an adjacent routing line by at least a first distance. The display also includes a interposer that is bonded to the surface. The interposer includes a first interface that connects the first plurality of conductive routing lines with the interposer. The interposer also includes a plurality of interposer routing lines that are connected to the first interface. Each of the plurality of interposer routing lines is separated from an adjacent interposer routing line by at least a second distance where the second distance is less than the first distance.

### TECHNICAL FIELD

This disclosure relates to the field of displays, and particularly to displays that include a narrow bezel.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

A display typically includes of an array (or matrix) of picture elements (“pixels”). Thousands or millions of these pixels together create an image on the display. The light modulators of the pixels are electronically driven by drive components, e.g., driver IC chips, which are located on the periphery of a display panel. A drive IC chip uses contact pads to connect with routing lines that conduct electrical signals to drive each row and column of the array of picture elements.

One problem is that displays typically use a glass substrate. Glass requires relatively coarse and wide conductive routing lines or paths (e.g., 3-5 microns wide). Because a display can have many rows of pixels that require many routing lines to drive the many rows, the bezel width of the display must be wide enough to accommodate the many rows of routing lines. With a design rule of about 3-5 microns for each routing path of the routing lines, the bezel size can be undesirably large, resulting in less room for the display area for a particular size of display backplane. It would be beneficial to have a display with a relatively narrow bezel which, in turn, enables a larger viewable display area for the same display substrate area.

### SUMMARY

The systems, methods and devices of this disclosure each have several innovative aspects, no single one of which is solely responsible for the desirable attributes disclosed herein.

The systems, methods and devices of this disclosure each have several innovative aspects, no single one of which is solely responsible for the desirable attributes disclosed herein.

One innovative aspect of the subject matter described in this disclosure can be implemented in an electronic device, e.g., a display, having a substrate including a surface. The display includes a first plurality of routing lines on the surface. Each of the first plurality of routing lines can be separated from an adjacent routing line by at least a first distance. The display also includes an interposer that is bonded to the surface. The interposer can include a first interface that connects the first plurality of conductive routing lines with the interposer. The interposer includes a plurality of conductive interposer routing lines that are also connected to the first interface. Each of the plurality of interposer routing lines can be separated from an adjacent interposer routing line by at least a second distance where the second distance being less than the first distance.

In some innovative implementations, the density of the plurality of interposer routing lines can be greater than the density of the first plurality of routing lines. The surface roughness of the interposer may be smoother than the surface roughness of the substrate. Also the flatness of the material used for the interposer may be flatter than the surface of the substrate. Furthermore, the interposer may include a plurality of layers where each layer includes at least one conductive routing line.

In some innovative configurations, the interposer can include a second interface that is connected to plurality of interposer routing lines and connected to a second plurality of conductive routing lines on the surface of the display substrate. Each of the second plurality of conductive routing lines can be separated from an adjacent routing line by at least the first distance. The substrate may be a glass or plastic substrate.

In some innovative implementations, at least one side of the interposer can be substantially aligned with an edge of the display substrate. The interposer may be bonded to the substrate using anisotropic conductive film (ACF). The interposer may include at least one conductive contact pad or bump that is connected to one of the display routing lines.

Another innovative aspect of the subject matter described in this disclosure can be implemented in an interposer having a first interface that connects the interposer to a first plurality of conductive routing lines on a display substrate where each of the first plurality of conductive routing lines can be separated from an adjacent conductive routing line by at least a first distance. The interposer can be bonded to the display substrate. The interposer also includes a plurality of interposer routing lines connected to the interface where each of the plurality of interposer routing lines is separated from an adjacent interposer routing line by at least a second distance such that the second distance is less than the first distance.

Another innovative aspect of the subject matter described in this disclosure can be implemented in a method for manufacturing a electronic device, e.g., a display, including providing a substrate including a surface. Then, arranging a first plurality of conductive routing lines on the surface where each of the first plurality of conductive routing lines is separated from an adjacent conductive routing line by at least a first distance. Then, providing an interposer including a first interface and arranging a plurality of interposer routing lines on the interposer. Further, connecting the plurality of interposer routing lines to the first interface where each of the plurality of interposer routing lines is separated from an adjacent interposer routing line by at least a second distance such that the second distance is less than the first distance. Then, bonding the interposer to the substrate and connecting the first plurality of conductive routing lines to the first interface.

In certain innovative implementations, a second interface can be arranged on the interposer where the second interface connects the plurality of interposer routing to a second plurality of conductive routing lines on the surface of the substrate.

Details of one or more implementations of the subject matter described in this disclosure are set forth in the accompanying drawings and the description below. Although the examples provided in this disclosure are primarily described in terms of Electromechanical Systems (EMS) and MEMS-based displays the concepts provided herein may apply to other types of displays such as liquid crystal displays (LCDs), organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A is an example of a display apparatus having MEMS elements.

FIG. 1B is a block diagram of the display apparatus of FIG. 1A.

FIG. 2A depicts in more detail a light modulator of the type depicted in FIG. 1A.

FIG. 2B depicts an alternate implementation of a light modulator of the type depicted in FIG. 1A.

FIG. 3 shows a prior art display including wide routing lines.

FIG. 4 depicts a display including an interposer.

FIG. 5 is an illustrative cross-sectional view of an interposer including multiple layers with routing lines.

FIG. 6 is an illustrative cross-sectional view of a bond between an interposer and a display substrate.

FIG. 7 is a flow diagram of a process for manufacturing a display including an interposer.

FIGS. 8A and 8B are system block diagrams illustrating a display device that includes a plurality of MEMS light modulator display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Certain implementations described herein propose fabricating the wiring (e.g., drive or routing lines) for a display in a way where the routing density is significantly denser based on incorporating an interposer onto the display substrate that has substantially finer design rules and tolerances, multi-layer capabilities, or both. In one aspect, the interposer is implemented such that the routing path tolerances of the interposer and surface roughness are substantially finer than the routing tolerances or surface roughness for glass, plastic, or another substrate used as a display backplane. The finer routing paths or lines are enabled by having an interposer substrate that has a lower surface roughness and that is flatter than the display substrate. The interposer may include a silicon-based substrate. However, any suitable material, having a finer routing design tolerance than the display substrate, may be used to increase the routing density. In one implementation, the interposer may provide a greater than ten (10) times increase in routing line density based on silicon design rules which are sub-micron, as opposed to 3-5 microns for a glass substrate. In certain implementations, a silicon chip with no active or passive devices (e.g., transistors, capacitors, resistors, and the like) may be used to route signals from driver circuitry to the rows of a pixel array in the viewable display area. In certain implementations, the interposer may include circuitry that enables signal routing, signal processing, or a combination of both functions. This routing substrate, or interposer, can have a surface roughness that is less than the surface roughness substrate that it is attached to and is flatter than the display substrate. In certain implementations, the surface roughness can be measured in root-mean-square roughness. In some implementations, the interposer can also be configured with multiple layers where each layer may include one or more conductive or metal routing lines.

Particular implementations of the subject matter described in this disclosure can be implemented to realize one or more of the following potential advantages. The systems and methods described herein substantially increase the density of the conductive routing lines along the bezel of a display which, in turn, reduces the required width or area of the bezel. Therefore, while less area is used for the bezel, a higher percentage of the total display area is made available for the viewable display area . A high viewable area percentage is desirable for many applications. In other cases, the cost of a display may be reduced by reducing the total size of a display backplane for the same viewable display area.

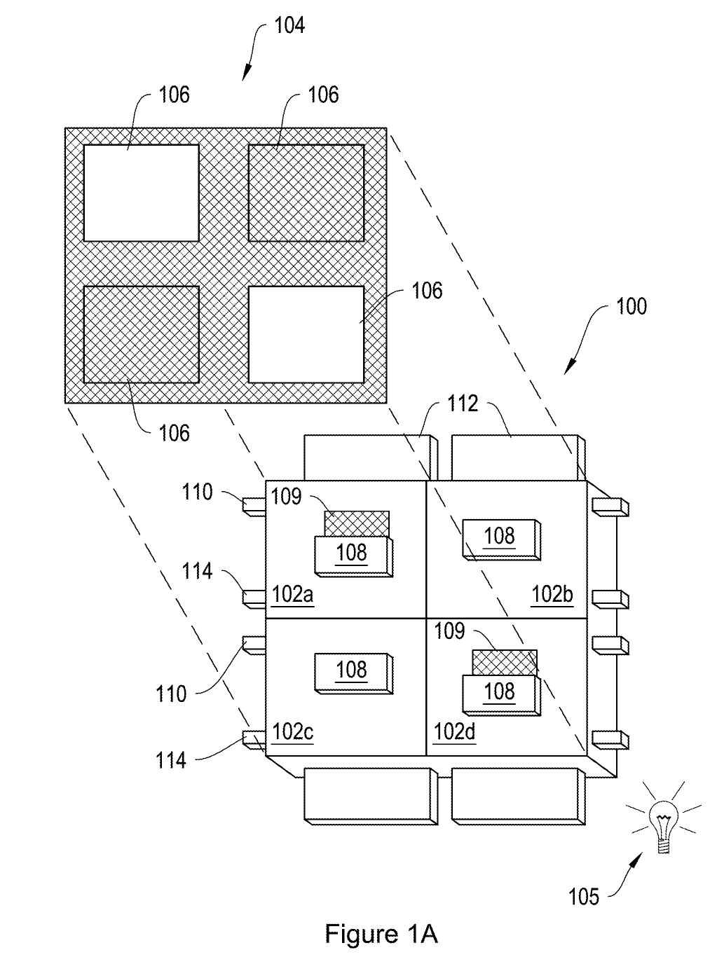

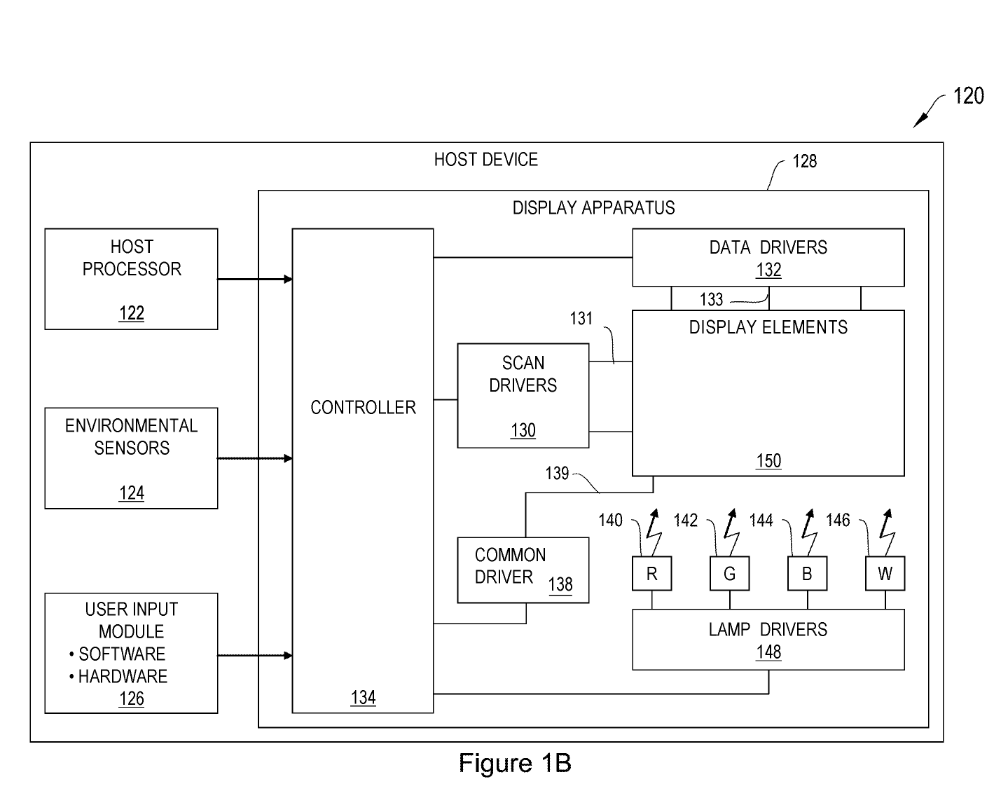

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

Each light modulator 102 can include a shutter 108 and an aperture 109. To illuminate a pixel 106 in the image 104, the shutter 108 is positioned such that it allows light to pass through the aperture 109. To keep a pixel 106 unlit, the shutter 108 is positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying only a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for only a certain fraction of the image is loaded to the array of display elements 150. For example, the sequence can be implemented to address only every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

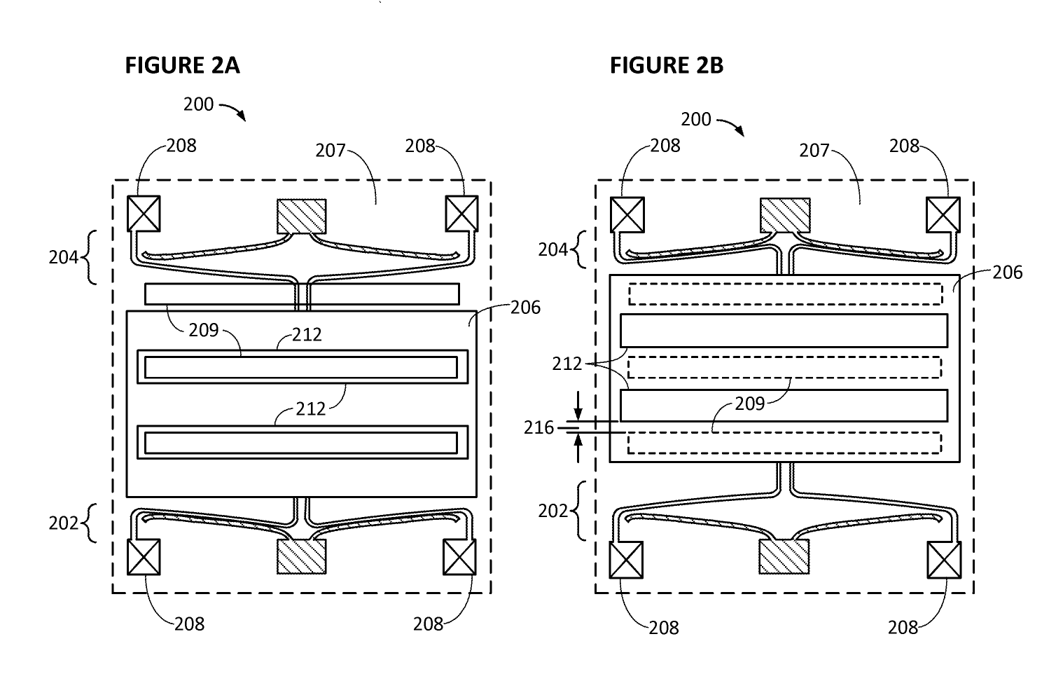

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have only a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

Electrical bi-stability in electrostatic actuators, such as actuators 202 and 204, can arise from the fact that the electrostatic force across an actuator is a function of position as well as voltage. The beams of the actuators in the shutter assembly 200 can be implemented to act as capacitor plates. The force between capacitor plates is proportional to 1/d² where d is the local separation distance between capacitor plates. When the actuator is in a closed state, the local separation between the actuator beams is very small. Thus, the application of a small voltage can result in a relatively strong force between the actuator beams of the actuator in the closed state. As a result, a relatively small voltage, such as Vₘ, can keep the actuator in the closed state, even if other elements exert an opposing force on the actuator.

In dual-actuator light modulators, the equilibrium position of the light modulator can be determined by the combined effect of the voltage differences across each of the actuators. In other words, the electrical potentials of the three terminals, namely, the shutter open drive beam, the shutter close drive beam, and the load beams, as well as modulator position, can be considered to determine the equilibrium forces on the modulator.

For an electrically bi-stable system, a set of logic rules can describe the stable states and can be used to develop reliable addressing or digital control schemes for a given light modulator. Referring to the shutter assembly 200 as an example, these logic rules are as follows:

If |Vₒ−Vₛ|<Vₘ and |V_{c}−Vₛ|<Vₘ (rule 1)

Then the shutter will relax to the equilibrium position of its mechanical spring.

If |Vₒ−Vₘ|<Vₘ and |V_{c}−Vₛ|<Vₘ (rule 2)

Then the shutter will not move, i.e., it will hold in either the open or the closed state, whichever position was established by the last actuation event.

If |Vₒ−Vₐₜ|<Vₘ and |V_{c}−Vₛ|<Vₘ (rule 3)

Then the shutter will move into the open position.

If |Vₒ−Vₘ|<Vₘ and |V_{c}−Vₛ|<Vₐₜ (rule 4)

Then the shutter will move into the closed position.

Let Vₛ be the electrical potential on the shutter or load beam. Let Vₒ be the electrical potential on the shutter-open drive beam. Let V_{c} be the electrical potential on the shutter-close drive beam. Let the expression |Vₒ−Vₛ| refer to the absolute value of the voltage difference between the shutter and the shutter-open drive beam. Let Vₘ be the maintenance voltage. Let Vₐₜ be the actuation threshold voltage, i.e., the voltage to actuate an actuator absent the application of Vₘ to an opposing drive beam. Let Vₘₐₓ be the maximum allowable potential for Vₒ and V_{c}. Let Vₘ<Vₐₜ<Vₘₐₓ. Then, assuming Vₒ and V_{c} remain below Vₘₐₓ:

Following rule 1, with voltage differences on each actuator near zero, the shutter will relax. In many shutter assemblies, the mechanically relaxed position is only partially open or closed, and so this voltage condition is usually avoided in an addressing scheme.

The condition of rule 2 makes it possible to include a global actuation function into an addressing scheme. By maintaining a shutter voltage which provides beam voltage differences that are at least the maintenance voltage, Vₘ, the absolute values of the shutter open and shutter closed potentials can be altered or switched in the midst of an addressing sequence over wide voltage ranges (even where voltage differences exceed Vₐₜ) with no danger of unintentional shutter motion. The conditions of rules 3 and 4 are those that are generally targeted during the addressing sequence to ensure the bi-stable actuation of the shutter.

The maintenance voltage difference, Vₘ, can be designed or expressed as a certain fraction of the actuation threshold voltage, Vₐₜ. For systems designed for a useful degree of bi-stability, the maintenance voltage can exist in a range between about 20% and about 80% of Vₐₜ. This helps ensure that charge leakage or parasitic voltage fluctuations in the system do not result in a deviation of a set holding voltage out of its maintenance range—a deviation which could result in the unintentional actuation of a shutter. In some systems, an exceptional degree of bi-stability or hysteresis can be provided, with Vₘ existing over a range of about 2% and about 98% of Vₐₜ. In these systems, however, care must be taken to ensure that an electrode voltage condition of |V_{c}−Vₛ| or |Vₒ−Vₛ| being less than Vₘ can be reliably obtained within the addressing and actuation time available. In some implementations, the first and second actuators of each light modulator are coupled to a latch or a drive circuit to ensure that the first and second states of the light modulator are the only two stable states that the light modulator can assume.

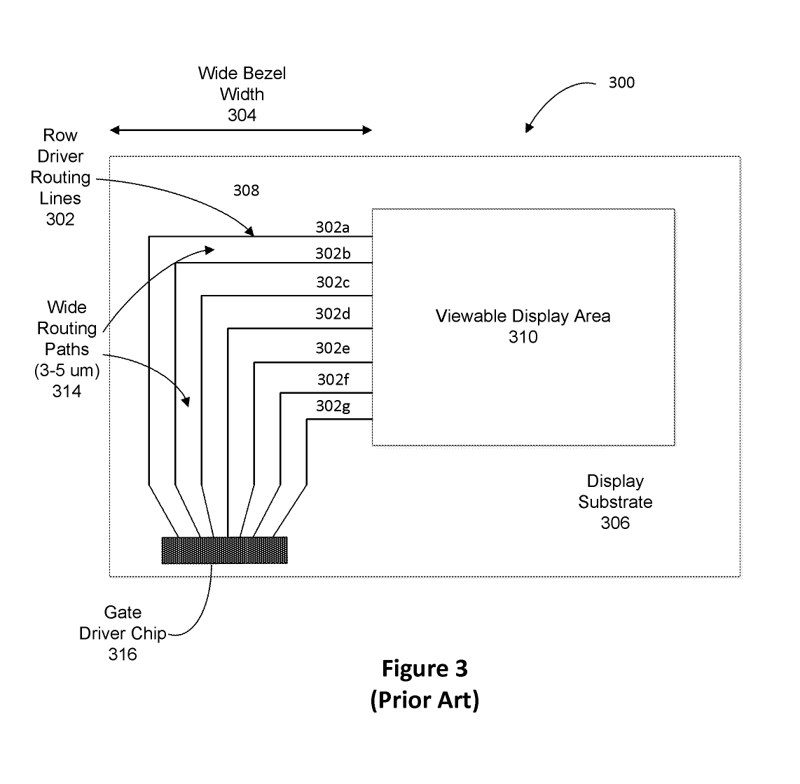

FIG. 3 shows a prior art display 300 including wide conductive routing lines 302a-302g. The display 300 has a bezel area 308 and a viewable display area 310. The display 300 may include a drive chip 316 that provides drive signals to operate light modulators associated with pixels of the display 300. The display 300, like most typical displays, uses a glass substrate 306. Glass requires relatively coarse and wide conductive routing lines 302 having routing paths that are about 3-5 microns wide. Because the display 300 can have many rows of pixels, requiring many conductive routing lines 302 to drive the many rows, the bezel width 304 must be wide enough to accommodate the many rows of conductive routing lines 302. With a design rule of about 3-5 microns for each conductive routing line 302, the bezel width 304 can be undesirably large, resulting in less room for the viewable display area 310 for a particular size of display backplane or substrate 306.

The display 300 typically includes of an array (or matrix) of picture elements (“pixels”). Thousands or millions of these pixels together create an image on the display 300 in the viewable display area 310. The light modulators of the pixels are electronically driven by drive components, e.g., driver IC chips such as driver chip 316, which are located on the periphery of the display substrate 306. A driver IC chip typically has many contact pads to connect with the conductive routing lines 302 that conduct electrical signals to drive each row and column of the array of picture elements of the display 300.

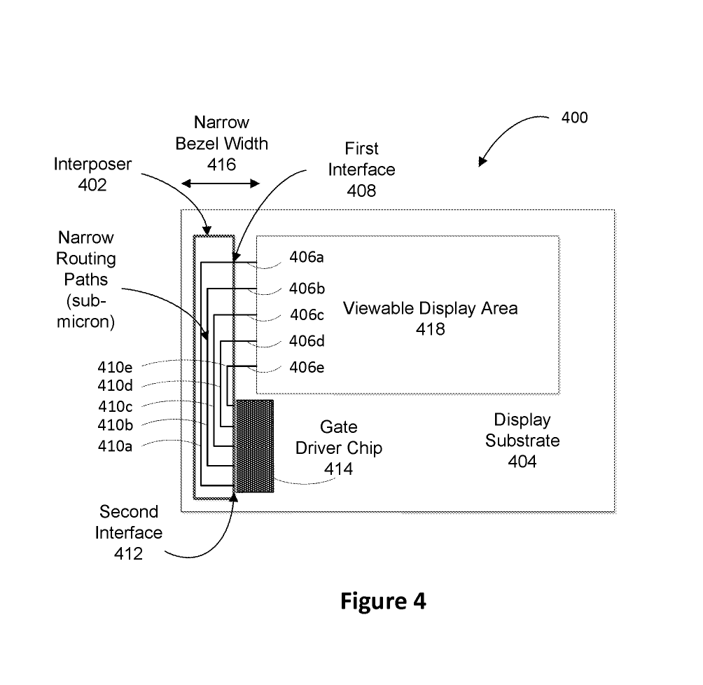

FIG. 4 depicts a display 400 including a routing substrate or interposer 402 and display substrate 404. The display substrate 404 includes a first plurality of conductive routing lines or substrate routing lines 406a-406e on a surface of the display substrate 404. Each of the display routing lines 406a-406e can be separated from an adjacent routing line by at least a first distance. The first distance may depend on, for example, design rules associated with material used for the display substrate 404. The first distance may be determined by the resolution and alignment capabilities of, for example, a lithography process or the uniformity and anisotrohy of an etching tool used to form the routing lines 406a-406e. The first distance may also depend on the surface roughness or the flatness of the material used for the display substrate. The more smooth and flat the surface of a material, then shorter the first distance on that material. For instance, if the material is glass, then first distance may be about 3 to 5 microns. The interposer 402 can be bonded to the surface of the display substrate 404. The interposer 402 can include a first interface 408 that connects the display routing lines 406a-406e with a second plurality of conductive routing lines or interposer routing lines 410a-410e on or within the interposer 402. Each of the interposer routing lines 410a-410e can be separated from an adjacent conductive routing line 410 by at least a second distance where the second distance being less than the first distance.

In some configurations, the interposer 402 can include a second interface 412 that connects the interposer routing lines 410a-410e with a driver chip 414. In other configurations, the second interface 412 connects the interposer routing lines 410a-410e to a third plurality of conductive routing lines or substrate routing lines on the surface of the display substrate 404, which may then connect with a driver chip 414 or other devices or circuitry. Each of the third plurality of conductive routing lines can be separated from an adjacent conductive routing line by at least the first distance. The driver chip 414 may be oriented such that a side including contact pads is adjacent a portion of the interposer 402. Hence, the driver chip 414 may be orientated vertically or horizontally with respect to the interposer 402 or the viewable display area 418. For example, FIG. 4 shows a driver chip 414 that is aligned vertically with the interposer 402 such that a side of the driver chip 414 including contact pads is aligned adjacent to a portion of interposer 402 including contact pads. In other implementations, the driver chip 414 can be aligned horizontally, for example, such that a side of the driver chip 414 including contact pads is positioned adjacent to an end of the interposer 402. Moreover, the driver chip 414 may be aligned adjacent to any portion of the interposer 402 depending on the arrangement of components on the display substrate 404 or the position of contact pads on the interposer 402.

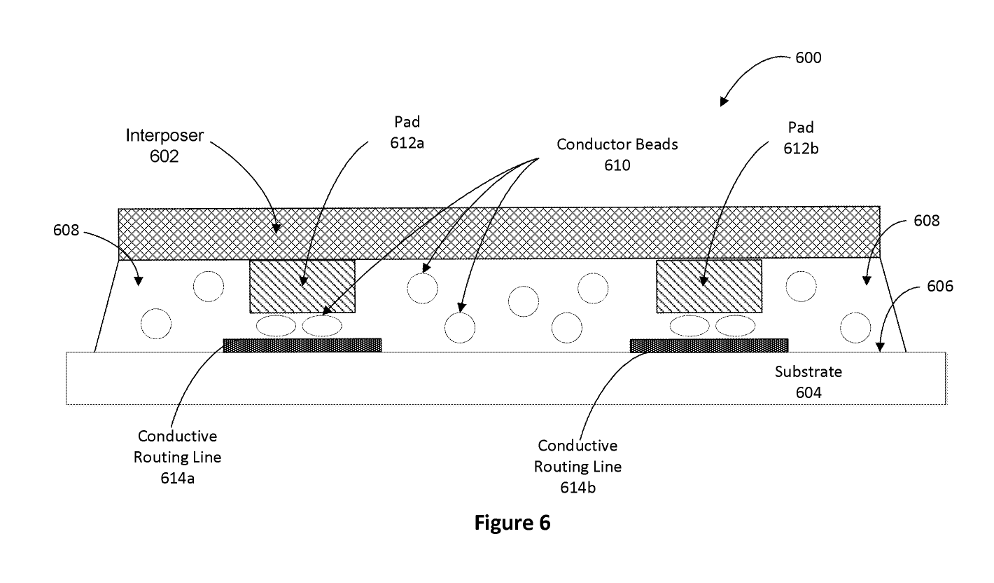

The display substrate 404 may include glass. At least one side of the interposer 402 can be substantially aligned with an edge of the display substrate 404. The interposer 402 may be bonded to the display substrate using ACF as illustrated later in FIG. 6, or by other chip bonding techniques. The interposer 402 may include one or more conductive contact pads that are connected to one or more conductive routing lines on the display substrate 404.

The density of the interposer routing lines 410a-410e can be greater than the density of the display routing lines 406a-406e. The flatness and thickness uniformity of the interposer 402 may be finer than the flatness and thickness uniformity of the display substrate 404. Furthermore, the interposer 402 may include a plurality of layers where each layer includes at least one conductive routing line 410. The interposer 402 may include a silicon-based substrate. However, any suitable material, having a finer routing design tolerance than the display substrate, may be used to increase the routing density. In one implementation, the routing line density based on silicon design rules may be less than about 1 micron, as opposed to 3-5 microns for a glass substrate.

FIG. 4 illustrates how the bezel width 416 of the display 400 is substantially narrowed with respect to the bezel width 304 of display 300 by employing an interposer 402 that increases the density of, for example, the conductive routing lines 410a-410e within the interposer 402 between the driver chip 414 and the viewable display area 418. While FIG. 4 illustrates how the density of the routing lines 410a-410e can be substantially increased horizontally (i.e., along the same horizontal surface of the interposer 402), an interposer 402 can also be configured with multiple layers where each layer may include one or more conductive or metal routing lines.

As previously discussed, the wiring (e.g., conductive routing lines) for the display 400 is arranged in a way where the routing density is significantly denser based on incorporating the interposer 402 onto the display substrate 404 where the interposer has substantially finer design rules and tolerances, and multi-layer capabilities. The interposer 402 can be implemented such that the routing line tolerances of the interposer 402 are finer because a surface of the interposer 402 is smoother, flatter, or both smoother and flatter than the surface of, for example, of glass, plastic or another substrate used as a display substrate 404. The interposer 402 may include a silicon-based substrate. However, any suitable material, having a finer routing design tolerance than the display substrate 404, may be used to increase the routing density. In one implementation, the interposer 402 may provide a greater than ten (10) times increase in routing line density based on silicon design rules which are less than 1 micron, as opposed to 3-5 microns for a glass substrate. The distance between interposer routing lines 410 may be less than about 1 micrometer, less than about 500 nanometers, less than about 250 nanometers, or less than about 100 nanometers. Furthermore, the interposer 402 may have multiple levels or layers of metal where, for the same routing line tolerances, n layers can reduce the required spacing for a single layer by about a factor of n.

In certain implementations, the interposer 402 may include a silicon chip with no active or passive devices (e.g., transistors, capacitors, resistors, and the like) to route signals from driver circuitry, e.g., driver chip 414, to the rows of a pixel array in the viewable display area 418. The interposer 402 can have a surface roughness that is less than the substrate 404 attached to the interposer 402. The surface roughness may be measured in root-mean-square roughness. Alternatively, an IC chip including at least one active device such as a transistor could also include one or more conductive routing lines that are or are not connected to an active device on the IC chip. Such an IC chip could also serve as an interposer to provide high density routing in addition to other control functions using active devices. In certain configurations, more than one interposer 402 may be used on a substrate, e.g., in a display device. For example, one interposer 402 may be used to connect a driver chip to rows of the display while a second interposer 402 may be used to connect another driver chip to the columns of the display.

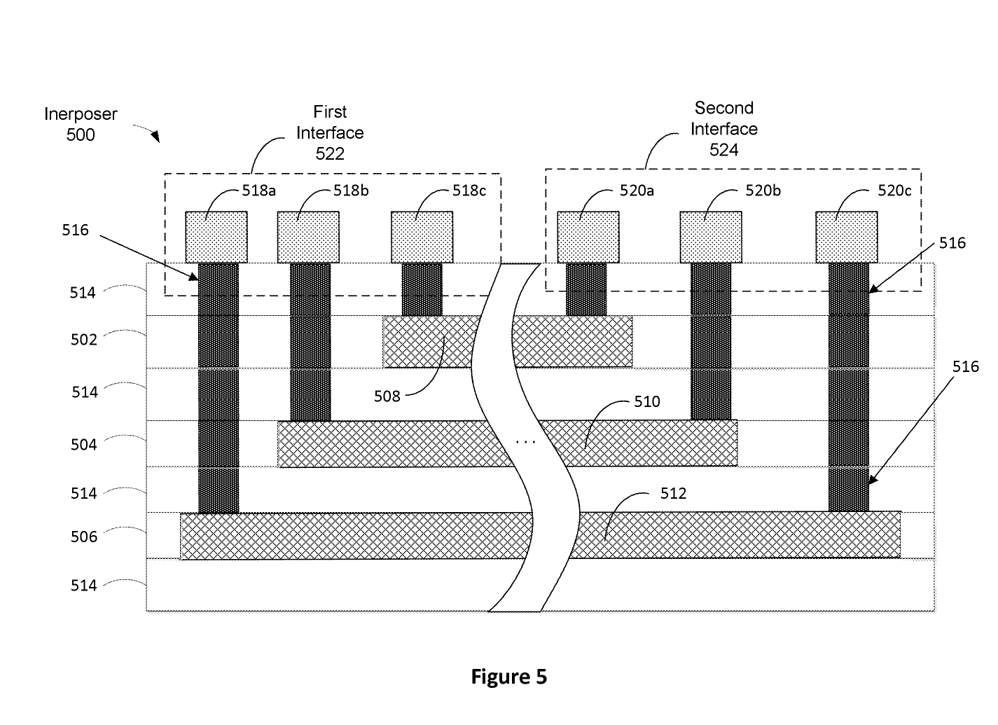

FIG. 5 is an illustrative cross-sectional view of a interposer 500 including multiple routing layers 502, 504, and 506, each having respective routing line 508, 510, and 512. Each of the routing layers 502, 504, and 506 are separated form each other by an insulating layer 514. The interposer 500 is oriented in the upward direction such that contact pads 518 and 520 are facing upwards. However, a person of ordinary skill will readily recognize that the interposer 500 may be oriented in a downward direction such that the contact bumps 518 and 520 are facing downward toward, for example, substrate 404 of FIG. 4. The interposer includes multiple vias 516 that are arranged to provide an electrically conductive connection between each contact pad 518 or 520 and its respective routing line 508, 510, or 512. For example, bump 518a is connected to routing line 512 by five vias 516 that are stacked through multiple layers of the interposer 500. Also, contact pad 520c is connected to routing line 512 by five vias 516 that are stacked through each of the five layers of the interposer 500 that are between the contact pads and the routing line. In this way, an electronic signal can be carried from contact pads 518a, at a first location of the interposer 500, to contact pad 520c, at a second location of the interposer. The interposer 500 includes a first interface 522 that includes one or more contact pads 518 that can be connected to a first set of conductive routing lines on a display substrate. The interposer 500 also includes a second interface 524 that includes one or more contact pads 520 that can be connected to second set of conductive routing lines on a display substrate. In this way, the routing the substrate 500 is able to route electronic signals via routing lines 508, 510, and 512 from one location (and one set of routing lines) on a display substrate to another location (and another set of routing lines) on the same display substrate.

While FIG. 5 shows a single routing line 508, 510, and 512 on each routing layer 502, 504, and 506 respectively, each routing layer 502, 504, and 506 may include multiple routing lines that are horizontally dispersed along each layer, which are also connected to distinct contact pads to facilitate distinct electrical connections between the first interface 522 and the second interface 524.

FIG. 6 is an illustrative cross-sectional view of a bond 600 between a interposer 602 and a display substrate 604. The interposer 602 can have one or more layers of conductive routing lines. The interposer 602 may be bonded to the display substrate 604 via asymmetric conductive film (ACF). The interposer may also be bonded to a glass substrate using typical chip on glass (COG) techniques. The connections may use contact pads, fixed pins, contact pads, or elastomer connectors, and the like. A contact pad may include a relatively tall structure that is plated to reach a multi-micron height. ACF may enable spacing such that pads similar to bonding pads on a silicon-based IC can be used by the interposer 602. In FIG. 6, the interposer 602 uses pads 612 in a face-down configuration to bond with the substrate 604. The bond in FIG. 6 is implemented using ACF where the ACF bond may include an epoxy 608 containing electrically conductive conductor beads 610. The conductor beads 610 that are pressed between the contact pads of the interposer 602 and associated routing lines 614 or associated contact pads of the substrate 604 enable electrical connection there between.

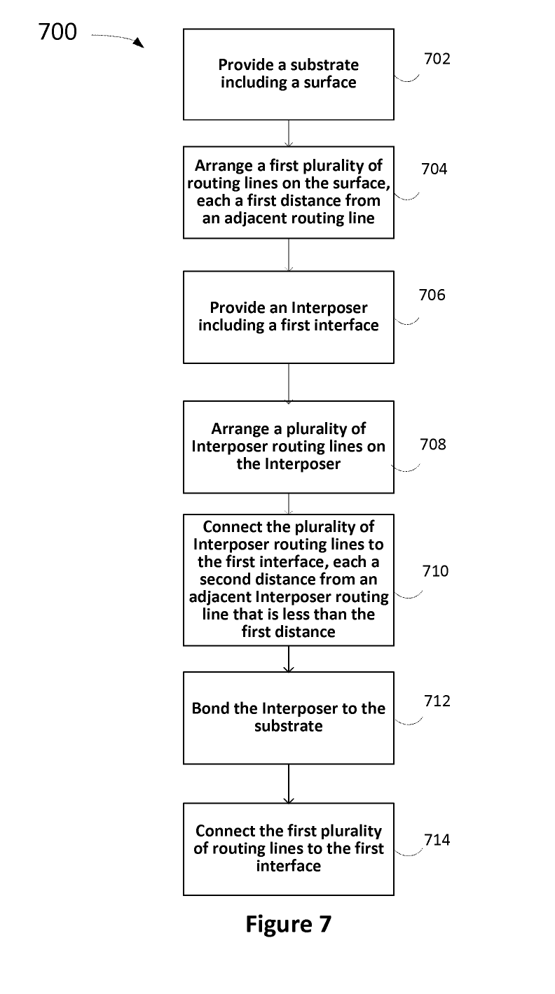

FIG. 7 is a flow diagram of a process 700 for manufacturing a electronic device such as, for example, display 400 of FIG. 4 including an interposer such as, for example, interposer 402. First, a display substrate 400 is provided that includes a surface (Block 702). Then, a first plurality of conductive routing lines, e.g., routing lines 406, are arranged on the surface where each of the first plurality of conductive routing lines 406 is separated from an adjacent conductive routing line by at least a first distance (Block 704). Then, an interposer 402 is provided that includes a first interface, e.g., interface 408 or 522 (Block 706). A plurality of conductive interposer routing lines 410 are arranged on the interposer 402 (Block 708). Further, the plurality of conductive interposer routing lines 410 are connected to the first interface 522 such that each of the plurality of conductive interposer routing lines 410 is separated from an adjacent conductive interposer routing line by at least a second distance where the second distance is less than the first distance (Block 710). The interposer 402 is bonded to the display substrate 404 (Block 712). The first plurality of conductive routing lines 406 are also connected to the first interface 522 (Block 714).

A second interface 412 or 524 can be arranged on the interposer 402 where the second interface 412 connects the plurality of conductive interposer routing lines 410 to a second plurality of conductive routing lines on the surface of the display substrate 404.

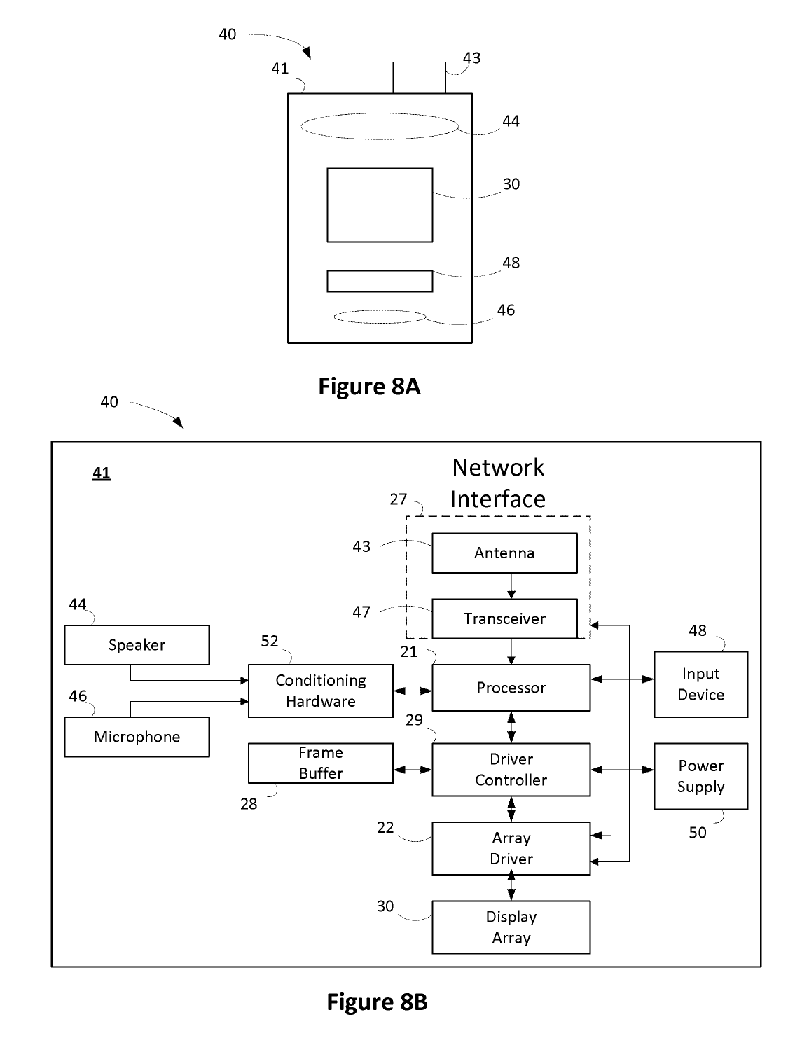

FIGS. 8A and 8B are system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 8B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 8A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a sub combination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An electronic device comprising:
a substrate including a surface;
a first plurality of conductive substrate routing lines on the surface, each of the first plurality of substrate routing lines being separated from an adjacent substrate routing line by at least a first distance; and
an interposer having a plurality of conductive interposer routing lines that are separated from each other by at least a second distance, the second distance being less than the first distance, the interposer having a first interface that is bonded to the surface of the substrate and where each interposer routing line is connected to an associated one of the first plurality of substrate routing lines.

2. The electronic device of claim 1, wherein a density of the interposer routing lines is greater than a density of the substrate routing lines.

3. The electronic device of claim 1, wherein a surface roughness of the interposer is finer than a surface roughness of the substrate.

4. The electronic device of claim 3, wherein the interposer includes a plurality of layers, each layer including at least one conductive routing line.

5. The electronic device of claim 1, wherein the interposer includes a second interface that is bonded to the surface of the substrate and where each interposer routing line is also connected to an associated one of a second plurality of conductive substrate routing lines.

6. The electronic device of claim 5, wherein each of the second plurality of substrate routing lines are separated from each other by at least the first distance.

7. The electronic device of claim 1, wherein the substrate is formed of a material consisting of at least one of glass or plastic.

8. The electronic device of claim 1, wherein at least one side of the interposer is substantially aligned with an edge of the substrate.

9. An interposer comprising:
a first interface for connecting the interposer to a first plurality of routing lines on a display substrate, each of the first plurality of routing lines being separated from an adjacent routing line by at least a first distance and the interposer being bonded to the display substrate; and
a plurality of interposer routing lines connected to the interface, each of the plurality of interposer routing lines being separated from an adjacent interposer routing line by at least a second distance, the second distance being less than the first distance.

10. The interposer of claim 9, wherein a density of the plurality of interposer routing lines is greater than a density of the first plurality of conductive routing lines.

11. The interposer of claim 9, wherein a surface roughness of the interposer is smoother than a surface roughness of the substrate.

12. The interposer of claim 11, wherein the interposer includes a plurality of layers, each layer including at least one interposer routing line.

13. The interposer of claim 9, wherein the first interface includes a plurality of pads, each pad being connected to one of first plurality routing lines.

14. The interposer of claim 9, comprising a second interface connected to the plurality of interposer routing lines and connected to a second plurality of routing lines on the surface of the substrate.

15. The interposer of claim 14, wherein each of the second plurality of routing lines is separated from an adjacent routing line by at least the first distance.

16. The interposer of claim 9, wherein the substrate includes a material consisting of at least on of glass and plastic.

17. A method for manufacturing an electronic device comprising:
providing a substrate including a surface;
arranging a first plurality of routing lines on the surface, each of the first plurality of routing lines being separated from an adjacent routing line by at least a first distance;
providing a interposer including a first interface;
arranging a plurality of interposer routing lines on the interposer;
connecting the plurality of interposer routing lines to the first interface, each of the plurality of interposer routing lines being separated from an adjacent interposer routing line by at least a second distance, the second distance being less than the first distance;
bonding the interposer to the substrate; and
connecting the first plurality o routing lines to the first interface.

18. The method of claim 17, comprising arranging a second interface on the interposer, the second interface connecting the plurality of interposer routing lines to a second plurality of routing lines on the surface of the substrate.
